(19) United States
(12) Patent Application Publication
(10) Pub. No.: US 2011/0309241 A1
(43) Pub. Date: Dec. 22, 2011

(54) INTERVENTIONAL INSTRUMENT WITH ILLUMINATION MEANS

(75) Inventors: Cristina Tanase, Waalre (NL); Herbert Lifka, Son (NL); Stein Kuiper, Neerijnen (NL)

(73) Assignee: KONINKLIJKE PHILIPS ELECTRONICS N.V., EINDHOVEN (NL)

(21) Appl. No.: 13/201,078

(22) PCT Filed: Feb. 8, 2010
(86) PCT No.: PCT/IB10/50549

§ 371 Date: Aug. 11, 2011

(30) Foreign Application Priority Data
Feb. 12, 2009 (EP) 09152700.2

(51) Int. Cl. H01J 40/14; H01L 31/12

(52) U.S. Cl. 250/216; 257/81; 257/E31.096

(57) ABSTRACT

The invention relates to an instrument (100) that can at least partially be inserted into an internal cavity (2) of an object (1), particularly a catheter or an endoscope. The instrument (100) comprises an optical system (OS) for collecting light coming from external objects through a viewing corridor (VC). The optical system comprises an OLED (110) for illuminating said external objects which is disposed in the viewing corridor (VC). In a particular embodiment, the OLED (110) may at least partially be transparent. By arranging the OLED (110) in the light corridor, an optimal illumination can be achieved together with a compact design of the whole instrument (100).

### FIELD OF THE INVENTION

The invention relates to an instrument like a catheter or an endoscope that can at least partly be inserted into an internal cavity of an object and that comprises illumination means. Moreover, the invention relates to an exchangeable component for such an instrument and to a method for examining an internal cavity of an object.

### BACKGROUND OF THE INVENTION

From the US 2005 0137459 A1 an endoscope is known that has an Organic Light Emitting Device (OLED) disposed around its tip for illuminating body cavities. Viewing of the body cavities is provided by a separate light corridor running along the endoscope.

### SUMMARY OF THE INVENTION

Based on this background it was an object of the present invention to provide means that allow an improved inspection of internal cavities, particularly when a close-up view is desired.

This object is achieved by an instrument according to claim 1, an exchangeable component according to claim 13, and a method according to claim 14. Preferred embodiments are disclosed in the dependent claims.

According to a first aspect, the invention relates to an instrument that can at least partially be inserted into an internal cavity of an object, for example into interstices of a machine or apparatus, or into a lumen of a human or animal body. In the latter case, the instrument may particularly be a catheter, an endoscope, a needle, or a similar (minimally) invasive instrument. The instrument comprises the following components:
a) An optical system for collecting light in an area called “target area”, said light coming from the outside of the instrument through a light corridor which will be called “viewing corridor” in the following. By definition the viewing corridor comprises the paths of all single light rays that come from infinity and are collected by the optical system, i.e. that reach the given target area. Practically, the collected light will come from external objects like the surfaces of an internal cavity that is inspected with the instrument, and the target area will for example correspond to the sensitive plane of an image sensor. The optical system may be designed for imaging or non-imaging applications. In imaging applications, the spatial relation between incoming light rays is preserved to allow the generation of an image of the object from which said light comes. In non-imaging applications, said spatial relation is not preserved or at least not evaluated (for example when the amount of fluorescence stimulated in an external object shall be determined by a single photodetector).
b) A lighting device like an Organic Light Emitting Device (OLED) that is part of the optical system and that is (completely or partially) disposed in the aforementioned viewing corridor. Light that propagates through the viewing corridor towards the optical system will therefore at least partially have to interact with the OLED, for example pass through a transparent OLED or be reflected by a reflective OLED. Designs of appropriate OLEDs are well known to a person skilled in the art and have been described in literature (e.g. Joseph Shinar (ed.): “Organic Light Emitting Devices, A survey”, Springer, 2004). Furthermore, an architecture of transparent OLEDs with a single sided emission will be described with respect to particular embodiments of the invention.

The described instrument provides an optimal illumination of internal cavities that shall be inspected and/or be optically manipulated because it uses an OLED for illumination that is disposed in the very viewing corridor through which light from an illuminated external object is collected. Thus the optical axes of the light source and of the viewing center can overlap, which guarantees an optimal, centered illumination of external objects without shadows or other disturbances. Moreover, the integration of the light source into the viewing corridor provides a compact design, which is particularly advantageous in medical applications in which the instrument has to be as small as possible.

According to a preferred embodiment of the invention, the OLED of the optical system may be transparent, i.e. it may by definition allow the passage of more than 10%, preferably more than 30%, most preferably more than 70% of the light intensity falling on it (from a given angle of incidence and from a given electromagnetic spectrum). Such a transparent OLED can readily be integrated into existing designs of optical systems.

The optical system may particularly comprise at least one lens for collecting and redirecting light that enters the instrument from the outside. Additionally or alternatively, it may comprise one or more optical waveguides for guiding light over extended spatial distances. In particular, optical fibers can be used to guide light from the head of the instrument, which is in a body cavity, along the axis of the instrument to devices outside the body.

The instrument may optionally comprise an image sensor, for example a CCD or CMOS chip. When connected to an appropriate optical system, the image sensor can be used to generate electronic images of external objects, for example of anatomical structures in a body cavity.

The OLED generally comprises an organic electroluminescent layer that is disposed between an anode and a cathode. When the anode and the cathode have different transmission characteristics, the emissions of the OLED to opposite sides will be different even if the light generation in the organic layer is isotropic. In an instrument according to the invention, an OLED with an asymmetric emission behavior is preferably disposed such that it has a higher emission in a direction away from the target area in which light shall be collected than towards it. The amount of light that illuminates an external object is then increased while the amount of light reaching the target area without coming from an external object is decreased. Preferably, the OLED emission in a direction away from the target area is more than 60%, preferably more than 80%, most preferably approximately 100% of the total light emission of the OLED.

In a preferred embodiment of the invention, the OLED is designed such that it comprises
an anode, a cathode, and an organic layer that is disposed between the anode and the cathode, wherein said organic layer, the anode, and the cathode constitute a structure in the organic layer with at least one electroluminescent zone and at least one not-electroluminescent (“inactive”) zone;
a mirror layer that has a structure with at least one nontransparent zone aligned to an electroluminescent zone and at least one transparent zone aligned to an inactive zone of the organic layer.

Via an at least partial alignment of the mentioned structures, such an OLED device can be made transparent for light and simultaneously emissive in a dominant (or even a single) direction. Thus the OLED can provide an optimal illumination of external objects while minimally interfering with internally generated images.

There are many different ways to arrange the OLED of the instrument in the viewing corridor. According to a first preferred embodiment, the OLED is disposed on a lens of the optical system. In this case the transparent lens can be used as the substrate that carries the light generating layers of the OLED. The arrangement on a lens of the optical system provides a very compact design of the whole instrument, particularly if a transparent OLED is used.

According to another embodiment, the OLED is arranged to be movable with respect to the target area. Changing the relative positions of the OLED and the target area can then be used to adjust and optimize illumination conditions, for example with respect to external objects at different distances from the instrument.

According to still another embodiment of the invention, the OLED is mounted in a cap that covers at least partially residual parts of the optical system. Preferably, the cap is a separate component that is movable with respect to the target area, thus additionally realizing the aforementioned embodiment of the instrument.

Furthermore, the OLED may be designed as an exchangeable component, for example by mounting it in a removable cap of the aforementioned kind. The OLED can then readily be removed and replaced, for instance in case of a defect or if an OLED with different properties shall be used. Moreover, medical applications can require the exchange of the OLED after each use for reasons of sterility.

In general, if the instrument is intended for medical applications, it is preferably designed such that it can be sterilized, i.e. the instrument is robust with respect to high temperatures (typically more than 100° C.) and/or to sterilizing chemicals. If the OLED is arranged as a separate, exchangeable component, only the residual instrument has to be sterilizable.

According to a further development of the invention, the OLED is composed of at least two sub-units that have illumination and/or transmission characteristics which are different from each other. The sub-units may be disposed in the viewing corridor, or at another location. Sub-units with different emission characteristics allow to adapt the illumination provided by the OLED, for example the color, intensity and/or direction of illumination light. The sub-units of the OLED may be disposed one upon the other and/or next to each other with respect to the propagation of light through the viewing corridor.

The invention further relates to an exchangeable component with an OLED for an instrument of the kind described above, i.e. an instrument with an optical system for collecting external light coming through a viewing corridor and with an OLED that is disposed in the viewing corridor. The exchangeable component may for example comprise disposable elements, including the OLED, that are required in medical applications to guarantee sterility. Typically, the exchangeable component and the instrument will simultaneously be designed to fit to each other. It is however also possible to design the exchangeable component in view of an already existing instrument, for example a standard catheter or endoscope, thus allowing to retrofit the instrument with the advantageous illumination means.

The invention further relates to a method for examining an internal cavity of an object, for example a body lumen, said method comprising the following steps:
a) Emitting light into said cavity with an OLED.
b) Collecting light coming from said cavity, wherein said light has been transmitted through the OLED and/or reflected by the OLED.

The method comprises in general form the steps that can be executed with an instrument of the kind described above. Therefore, reference is made to the preceding description for more information on the details, advantages and improvements of that method.

### BRIEF DESCRIPTION OF THE DRAWINGS

These and other aspects of the invention will be apparent from and elucidated with reference to the embodiment(s) described hereinafter. These embodiments will be described by way of example with the help of the accompanying drawings in which:

FIG. 1 schematically illustrates a first interventional instrument according to the invention with an OLED disposed directly on a lens;

FIG. 2 schematically illustrates the tip of a second interventional instrument according to the invention with an OLED disposed in a movable cap;

FIG. 3 schematically illustrates the arrangement of layers in a transparent OLED;

FIG. 4 schematically illustrates the arrangement of layers in a transparent OLED with a single-sided emission;

FIGS. 5-7 illustrate different arrangements of several OLED sub-units on the exit window of an interventional instrument.

Like reference numbers or numbers differing by integer multiples of 100 refer in the Figures to identical or similar components.

### DESCRIPTION OF PREFERRED EMBODIMENTS

The present invention will in the following be described with respect to an application in medical instruments, though the invention is not restricted to this case and can favorably be applied in many other situations, too.

In endoscopic apparatuses, light guides can for example be used to conduct the flow of light from a light source placed outside the endoscope and outside the body of a patient to be examined. In this situation the light source is too big or gets too hot to be placed inside the endoscope, respectively inside the body. When inorganic LEDs are used as light sources integrated to an endoscope, they must have a good heat sink; often they are too bulky for many endoscopic interventions. Moreover, known illumination solutions suffer from a non-uniform light distribution very close to an object (called “macro imaging”), and often the images obtained suffer from shadow due to the fact that the light is a point source. To circumvent this, the light source may be placed in a ring around the camera lens, but this consumes precious lateral space. Moreover, in macro imaging such a ring provides only little light in the centre of the object.

It is therefore desirable to have in endoscopy a light source that provides enough and uniform illumination of objects (organs, tissues, etc.) observed from a close distance. According to the present invention, this object can be achieved by integrating OLEDs, that are by definition uniform large area light sources, into the viewing corridor. Besides, high contrast can be obtained.

FIG. 1 shows schematically a medical instrument 100, e.g. an endoscope or a catheter, according to a first realization of the aforementioned general concept. The instrument 100 is disposed with its distal tip portion 101 in an internal cavity 2 of a body 1, for example in the ventricle of the heart of a patient. The proximal end of the instrument 100 (right side in the Figure) is disposed outside the body and connected to various external devices.

The instrument 100 comprises an optical system OS, which is here mainly represented by a simple convergent lens 120. The optical system OS is designed for collecting light that comes through a viewing corridor VC from external objects, for example from the inner surface of the cavity 2, in a “target area” TA (i.e. a given area that is typically fixed with respect to the instrument 100). In the shown example, the target area TA corresponds to the sensitive plane of an imaging sensor 130, where the collected light is transformed into an electronic image of the environment. The electronic image signals are transferred by an electrical cable 151 to an external image processing device 152.

To provide for an optimal illumination of the internal body cavity 2, the optical system OS of the instrument 100 comprises a transparent OLED 110 that is disposed directly on the lens 120 of the optical system. The OLED 110 is connected via electrical leads 141 to an external driver 142 such that it can selectively be provided with electrical energy. If activated, the OLED 110 emits light into the body cavity 2, thus illuminating the objects that shall be viewed. As the OLED 110 is disposed in the viewing corridor VC, the illumination is achieved without throwing shadows and with optimal (highest) intensity in the centre of the viewing field.

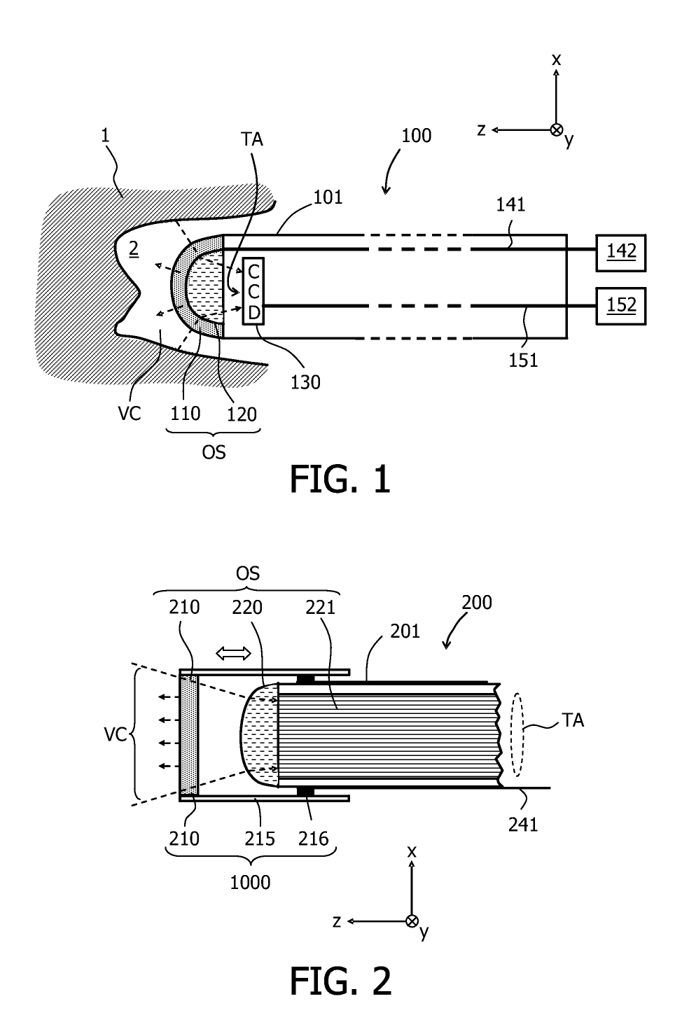

FIG. 2 shows a second embodiment of an instrument 200 with an alternative design. Only the tip 201 of his instrument is shown as the proximal end is similar to that of FIG. 1. The instrument 200 comprises as a first component of an optical system OS a lens 220. The lens 220 collects light that comes from external objects (not shown) through a viewing corridor VC. Behind the lens 220 the collected light enters into an optical fiber 221 as a second component of the optical system OS. The optical fiber 221 serves as a waveguide that guides the light to a target area TA, e.g. the sensitive plane of an image sensor disposed outside the body (not shown).

The optical system OS further comprises a transparent OLED 210 that is mounted at one end of a cylindrical cap 215, wherein said cap 215 covers with its opposite, open end the tip 201 of the instrument 200 and in particular the lens 220. Again the arrangement is such that all incoming light passes through the OLED 210, i.e. that the OLED is disposed in the viewing corridor VC. The cap 215 further comprises contact terminals 216 at its inner surface via which the OLED 210 is electrically coupled to lines 241 leading to an external driver (not shown) of the OLED.

As indicated by a double arrow, the cap 215 with the OLED 210 is preferably designed to be movable in axial direction of the instrument (z-direction) relative to the tip 201. The distance between the OLED 210 and the lens 220 can thus be adjusted in dependence on the observation requirements.

The cap 215 with the OLED 210 is preferably designed as a separate, exchangeable component 1000 which can readily be removed from the tip 201 of the instrument 200 and be replaced with a new one. The OLED 210 can thus particularly be a part of a disposable product 1000 to guarantee sterility of the whole system at the beginning of a new examination procedure even if the OLED as such would not be robust enough to withstand a sterilization procedure.

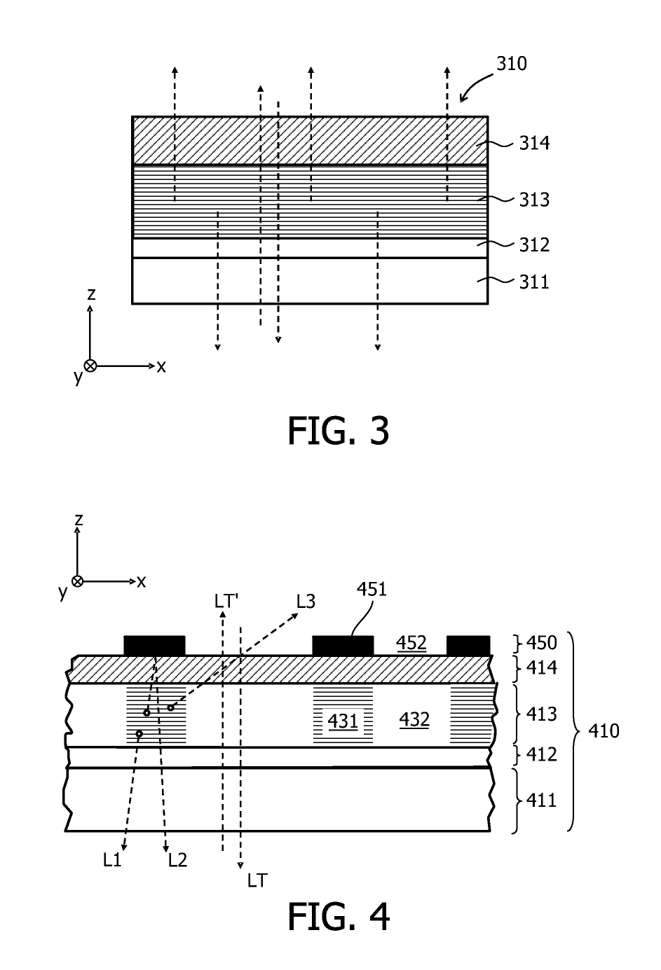

An important component of the described systems is the transparent OLED. FIG. 3 shows schematically a general layered design of a transparent OLED 310 as it might for example be used in the instruments 100, 200. The OLED 310 comprises, from bottom to top, the following layers:
a transparent substrate 311, for example made from glass or plastic with a water barrier;
a transparent cathode 312, for example made from indium tin oxide (ITO);
an organic electroluminescent layer 313, for example comprising small molecules (smOLED) or polymers (Polymer-OLED);
a transparent anode 314, for example made from Ag.

The OLED 310 may be produced by sequentially depositing the cathode 312, the organic layer 313, and the anode 314 on the substrate 311. It will usually comprise some further components like an encapsulation that are not shown in the Figure for clarity. As the electrode layers 312, 314 are transparent, the isotropic light generation in the organic layer 313 causes an active light emission through both the upper and the lower side of the OLED 310, and the complete OLED 310 is transparent for external light.

The emission of the OLED is not be necessarily the same to both sides but it can be regulated for instance by a smart optical design of different layers placed on the cathode. For example the light ratio between transmitted light by the anode and cathode can be 50:50, but it can also be 80:20, or even 100:0. The anode 314 of the OLED 310 injects electrical charges into the organic layer 313, but it can also have the role to adjust the transparency and the amount of light emitted through the anode and through the cathode. Depending on the OLED layer stack definition and on the optical stack for controlling the anode:cathode ratio, the transparency of the OLED can be up to 80-85% in the whole visible range.

As described above, the transparent OLED 310 can be placed on top of a lens (cf. FIG. 1) or in front of and at a certain distance from a lens (cf. FIG. 2). In the first case the OLED is preferably fabricated directly on top of the lens, the latter serving as substrate 311. In both cases the concept can be made such that either the OLEDs are considered consumables and not reused or that they can be subject to sterilization and be reused.

The described concept has the advantage that the whole area of interest is illuminated with homogeneous, diffuse light. Moreover, the contrast can be increased if the light source is tuned such that the transparent OLED has an uneven light emission, e.g. if most of the light is sent through the anode (up to 80%) and less light through the cathode. The object of interest is then illuminated by placing the OLED with the anode side aimed towards the object and the image is captured through the OLED.

For endomicroscopy the described advantages are exploited to the maximum because microscopes usually have a small working distance and in that case a conventional light source would not be able to light an object well.

In general, the transparency and the emission through the cathode are coupled. A high transparency means for example a high emission through the cathode. In the following table 1 a calculation of contrast CX from different anode:cathode ratio situations is presented. It can be observed that the contrast is improved by increasing the light emission through the anode via light reflection by the cathode. However, the resulting decrease in overall transparency of the OLED results in a decrease in image intensity on the image sensor, as this intensity scales with cathode transparency (TC) as TC². The optimum cathode transparency is therefore dependent on the image sensor sensitivity, object reflectance and OLED intensity. A higher sensitivity, reflectance and OLED intensity allow for a lower TC and thus lead to a higher contrast, while maintaining the image intensity on the sensor sufficiently high for imaging.

TABLE 1
Contrast CX depending on transparency TC of the cathode
(under the assumption that the anode has a constant transparency of 1 and that light not
emitted through the cathode is redirected and emitted through the anode).

| TC | LA | LC | OR | LI | CX | OR | LI | CX |
|---|---|---|---|---|---|---|---|---|
| 1 | 0.5 | 0.5 | 0.3 | 0.3 | 0.3 | 0.4 | 0.4 | 0.4 |
| 0.8 | 0.6 | 0.4 | 0.3 | 0.192 | 0.36 | 0.4 | 0.256 | 0.48 |
| 0.6 | 0.7 | 0.3 | 0.3 | 0.108 | 0.42 | 0.4 | 0.144 | 0.56 |
| 0.4 | 0.8 | 0.2 | 0.3 | 0.048 | 0.48 | 0.4 | 0.064 | 0.64 |
| 0.2 | 0.9 | 0.1 | 0.3 | 0.012 | 0.54 | 0.4 | 0.016 | 0.72 |
| 0 | 1 | 0 | | 0 | | | 0 | |

TC = transparency cathode
LA = light emitted through anode
LC = light emitted through cathode
OR = object reflectance
LI = Light intensity of image on image sensor (max. 1 for OR = 1)
CX = contrast image light to camera

FIG. 4 shows in a schematic sectional side view the design of an OLED 410 which is transparent but has a single-sided emission and with which an increased contrast can be achieved. Seen in the positive z-direction of the corresponding coordinate system, the OLED device 410 comprises the following sequence of layers:
A transparent substrate 411, for example made from glass or a transparent plastic with a water barrier.
A first transparent electrode layer 412, called “anode”, that may for example consist of ITO, doped zinc-oxide or an organic layer such as PEDOT:PSS, possibly in combination with a fine metal grid structure to lower the effective sheet resistance.
An organic layer 413 that is functionally (and, in this embodiment, also physically) structured into electroluminescent zones 431 and inactive (i.e. not electroluminescent) zones 432, wherein said zones are arranged next to each other in x-direction and extend through the complete organic layer in z-direction. In the electroluminescent zones 431, light is generated by the processes known from conventional OLEDs when electrons and holes injected into this layer from different sides recombine. The inactive zones 432 typically consist of modified material of the electroluminescent zones 431. In general, the inactive zones might however consist of a completely different (organic or anorganic) material.
A second transparent electrode layer 414, called “cathode”, that is for example constituted by a thin layer of silver (Ag).
A “mirror layer” 450 that consists of a pattern of nontransparent zones 451 and transparent zones 452. In the example of FIG. 4, the structure of the mirror layer 450 is in global and locally perfect alignment with the structure of the organic layer 413, wherein the alignment is judged with respect to a given alignment direction (z-direction in the shown embodiment). As suggested by the Figure, the transparent zones 452 may simply be empty, i.e. open to the environment. Preferably, the OLED device 410 is however finished and sealed on its top side by some transparent packaging that is not shown in the Figure.

When an appropriate voltage is applied between the anode 412 and the cathode 414, light will be generated in the electroluminescent zones 431. As indicated by light ray L1, a part of this light will immediately be directed to the substrate 411 and leave the OLED device 410 as desired through its front side (bottom in the Figure).

As indicated by light ray L2, another part of the generated light will be emitted in the opposite direction (positive z-direction) towards the back side of the OLED device 410. Due to the nontransparent zones 451 of the mirror layer 450, an emission through the back side is however blocked. As the nontransparent zones 451 are typically reflective on their bottom side, the light ray L2 is not simply absorbed but instead reflected and will thus be able to leave the OLED 410 through the front side, too. The Figure further illustrates a light ray L3 that is emitted by the OLED towards the cathode 414 and can leave the OLED device 410 through the transparent zones 452.

As indicated by light rays LT and LT′, environmental light can freely pass through the OLED device 410 in the transparent zones 452 of the mirror layer. As a consequence, the OLED device 410 will appear (at least partially) transparent and have at the same time a dominant or primary direction of active light emission (negative z-direction in FIG. 4).

In the embodiments of the invention shown in FIGS. 1 and 2, a uniform monochromatic transparent OLED is placed on the front side of an endoscope lens (FIG. 1) and at a the distance from the lens (FIG. 2), respectively. The transparent OLEDs are meant for illuminating an object situated at a certain distance, and they are as large as the lens.

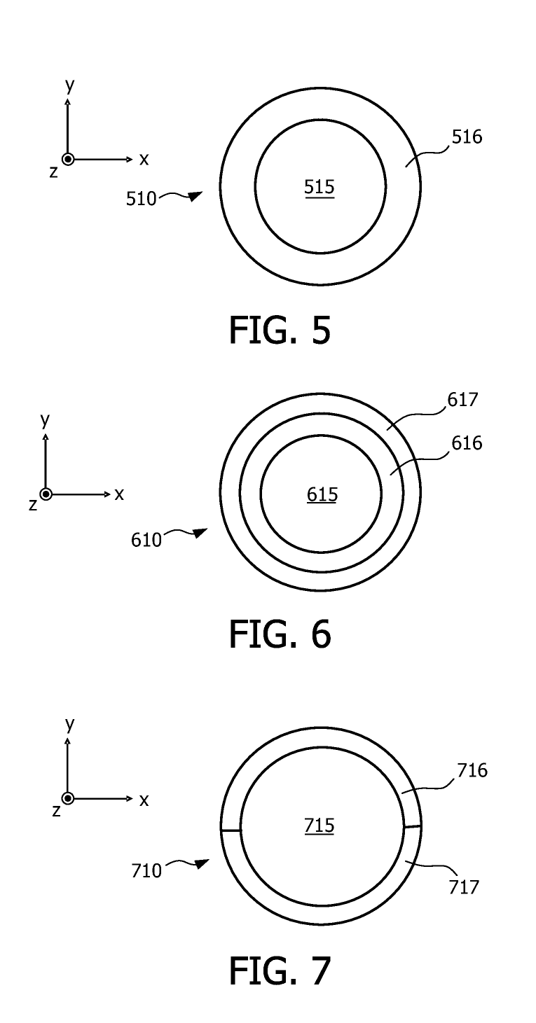

FIG. 5 shows in a view along the (z-) axis of an instrument according to the invention an OLED 510 that has been processed such that one central, circular area 515 is transparent (smaller than the endoscope lens) and another, annular area 516 around the transparent one is not transparent and emits light (only) to the front side, i.e. towards an object of observation. The OLED 510 is centered with respect to the front side of the endoscope lens, and the distance between lens and OLED is adjustable.

The OLED 510 may emit one-color light or white light. Alternatively, the system may contain two or more OLED sub-units emitting different colors. Such sub-units should be individually addressable and can optionally be used for different purposes. A transparent sub-unit can for example be used for observation and another (nontransparent) sub-unit can be used for wound treatment with light (e.g. UV light used as light therapy), or for the activation of chemicals with light of different wavelengths. Manipulations and modifications done with such an instrument can at the same time be observed.

FIG. 6 shows in a similar axial view an OLED 610 that comprises three concentrically arranged sub-units, for example a central circular, transparent sub-unit 615 together with an inner and an outer annular sub-unit 616, 617.

FIG. 7 shows a similar embodiment of an OLED 710 that comprises a central circular, transparent sub-unit 715 together with two sub-units 716, 717 in the form of a half ring.

The described system with an OLED as illuminating (transparent) window can be used for different types of endoscopes, catheters etc. for outside or inside body investigations and wound healing. It is particularly advantageous for endomicroscopes.

It should be noted that the invention comprises also embodiments in which one or more non-transparent OLEDs are disposed in the viewing corridor of an instrument. Thus it is for example possible to use an OLED (with a reflective back side) as a light-emitting mirror in the optical system of an instrument, which mirror reflects incoming light rays towards a target area and emits light to the outside.

Regarding the placement of non-transparent OLED structures, the following remarks apply:
The OLED structures should preferably be placed in the principal plane of a corresponding lens system (where usually the diaphragm is placed), as this is the place where objects in the optical path are not imaged on the sensor. They only reduce the light homogeneously.
The OLED structures should preferably be irregular to prevent diffraction.
Regarding resolution it would be advantageous to place a non-transparent OLED as a disc on the centre of a lens (rather than in a ring on the outside of the lens because the latter would reduce the NA of the lens).
All OLEDs should preferably be placed on the outside of the endoscope (or as far to the outside as possible) to reduce internal light reflections giving rise to stray light.

In summary, it is proposed to use OLEDs as light source for an instrument like an endoscope. Such an instrument provides improved image quality of internal organs or tissues without distortions or degradation of the image observed from a very small distance. The OLED light source may be applied independently on top of a lens or even technologically processed as being part of a lens. In this way the image observed gets high quality without shadow effects and the instrument can get multiple functionalities such as observation, detection of tumors, or treatment by only changing the lens on top. Another advantage over conventional endoscope lighting is lateral space reduction, which is crucial in keeping the endoscope diameter small.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. An instrument that can at least partially be introduced into an internal cavity of an object, comprising:
a) an optical system for collecting light in a target area, wherein the light comes from the outside through a viewing corridor;
b) a lighting device that is part of the optical system and at least partially disposed in the viewing corridor.

2. The instrument according to claim 1, characterized in that the lighting device is an OLED.

3. The instrument according to claim 2, characterized in that the OLED is transparent.

4. The instrument according to claim 1, characterized in that the optical system comprises a lens and/or a waveguide.

5. The instrument according to claim 1, characterized in that it comprises an image sensor.

6. The instrument according to claim 2, characterized in that the OLED has a higher emission in a direction away from the target area than towards it.

7. The instrument according to claim 2, characterized in that the OLED comprises
an anode, a cathode, and an organic layer that is disposed between the anode and the cathode, wherein said organic layer, the anode, and the cathode constitute a structure in the organic layer with at least one electroluminescent zone and at least one not-electroluminescent zone;
a mirror layer that has a structure with at least one nontransparent zone aligned to an electroluminescent zone and at least one transparent zone aligned to a not-electroluminescent zone of the organic layer.

8. The instrument according to claim 2, characterized in that the OLED is disposed on a lens of the optical system.

9. The instrument according to claim 2, characterized in that the OLED is movable with respect to the target area.

10. The instrument according to claim 2, characterized in that the OLED is mounted in a cap.

11. The instrument according to claim 2, characterized in that the OLED is designed as an exchangeable component.

12. The instrument according to claim 2, characterized in that the OLED is composed of at least two sub-units with different emission and/or transmission characteristics.

13. The instrument according to claim 1 for use in medical applications.

14. An exchangeable component for an instrument according to claim 2, said component comprising a transparent OLED to be placed into the viewing corridor of the instrument.

15. A method for examining an internal cavity of an object, comprising:
a) emitting light into said cavity with an OLED;
b) collecting light coming from said cavity that has been transmitted through and/or reflected at the OLED.
